(19) United States
(12) Patent Application Publication
(10) Pub. No.: US 2020/0333677 A1
(43) Pub. Date: Oct. 22, 2020

(54) ENERGY-AUTONOMOUS DISPLAY UNIT

(71) Applicant: Lufthansa Technik AG, Hamburg (DE)

(72) Inventor: Philip Woll, Hamburg (DE)

(21) Appl. No.: 16/848,860

(22) Filed: Apr. 15, 2020

(30) Foreign Application Priority Data
Apr. 18, 2019 (DE) 10 2019 110 353.3

(51) Int. Cl. G02F 1/1685; G02F 1/167; G02F 1/16755; G02F 1/133; G02F 1/1333; H01L 31/053; H01L 27/32; H01L 51/00; G06F 3/041; B64D 11/00

(52) U.S. Cl. CPC G02F 1/1685; B64D 2211/00; G02F 1/16755; G02F 1/13306; G02F 1/133305; G02F 1/13338; H01L 31/053; H01L 27/3227; H01L 27/323; H01L 51/0097; G06F 3/041; B64D 11/0015; G02F 2001/13324; H01L 2251/5338; G06F 2203/04102; G02F 1/167

(57) ABSTRACT

An energy-autonomous display unit for a cabin of a vehicle includes: a display element for displaying information on a display surface; an energy store; a controller; and a photovoltaic element. The photovoltaic element is connected to the energy store and is configured to charge the energy store. The energy store is connected to the display element and the controller for supplying energy. The controller is configured to control the display element and the information displayed on the display surface. The photovoltaic element is a transparent solar cell extending across the entire display surface of the display element. The photovoltaic element is a first layer on the display element.

### CROSS-REFERENCE TO PRIOR APPLICATIONS

Priority is claimed to German Patent Application No. DE 10 2019 110 353.3, filed on Apr. 18, 2019, the entire disclosure of which is hereby incorporated by reference herein.

### FIELD

The present invention relates to an energy-autonomous display unit for the cabin of vehicles, in particular of aircraft.

### BACKGROUND

In the cabin of vehicles, for example, aircraft, in particular commercial aircraft, information is made available to the passengers in various ways.

Ostensibly static information is periodically printed on films and is either placed in frames and holders in the aircraft cabin, which are provided for this purpose, or is affixed directly to the cabin wall or equipment provided in the cabin. For information that changes during the course of a flight, screens and optionally illuminated information lights are provided, which are distributed across the cabin and to which the respective information to be issued (for example, with respect to its size or the color rendition characteristics) is adapted. Finally, in modern commercial aircraft, individual monitors can still be provided for each passenger seat, on which, in addition to general and centrally controlled information, the in-flight entertainment can also be offered.

Printing information on films is disadvantageous, because it is limited in practice to static information. Changing the information reproduced on a film would in fact mean completely replacing the film, which is highly laborious, in particular in the case of affixed films.

Screens and information lights have the disadvantage that, even if they only display content that changes very seldom, they must be laboriously connected to the power supply of the aircraft. As a result, it is generally not possible to freely select the position of the screens inside the aircraft cabin.

### SUMMARY

In an embodiment, the present invention provides an energy-autonomous display unit for a cabin of a vehicle. The display unit includes: a display element for displaying information on a display surface; an energy store; a controller; and a photovoltaic element. The photovoltaic element is connected to the energy store and is configured to charge the energy store. The energy store is connected to the display element and the controller for supplying energy. The controller is configured to control the display element and the information displayed on the display surface. The photovoltaic element is a transparent solar cell extending across the entire display surface of the display element. The photovoltaic element is a first layer on the display element.

### BRIEF DESCRIPTION OF THE DRAWINGS

Embodiments of the present invention will be described in even greater detail below based on the exemplary figures. The present invention is not limited to the exemplary embodiments. All features described and/or illustrated herein can be used alone or combined in different combinations in embodiments of the present invention. The features and advantages of various embodiments of the present invention will become apparent by reading the following detailed description with reference to the attached drawings which illustrate the following:

FIG. 1 illustrates a first exemplary embodiment of a display unit according to the present invention; and

FIGS. 2a and 2b illustrate sectional view of the display unit according to FIG. 1 in two embodiment variants.

### DETAILED DESCRIPTION

Embodiments of the present invention provide a display unit for the cabin of aircraft, in which the disadvantages known from the prior art no longer occur or occur only to a minor degree.

Accordingly, the present invention relates to an energy-autonomous display unit for the cabin of vehicles, including a display element for displaying information on a display surface, an energy store, a control unit, and a photovoltaic element. The photovoltaic element is connected to the energy store for charging the energy store. The energy store is connected to the display element and the control unit for providing energy. The control unit is configured for controlling the display element and the information displayed on its display surface. The photovoltaic element is a transparent solar cell extending across the entire display surface of the display element, whereby the photovoltaic element is a first layer on the display element.

First, some terms used in connection with the present invention will be described.

A unit is considered to be “energy-autonomous” in the context of the present invention if forms of energy that are available locally at the unit are used exclusively for its electrical supply, and an external supply with electrical energy and conductors required therefor are completely omitted. “Locally available forms of energy” are in particular such forms of energy that act on the unit generally or for reasons other than specifically for the purpose of supplying energy, for example, light for illuminating the surroundings.

“Display surface” refers to the surface of a display on which the information to be displayed is output in a visually perceptible manner.

A “layer” is an element having a thickness which is orders of magnitude smaller than its length and width. A unit has a “multilayer structure” if multiple identical or different layers are joined in a layered manner to form a unit, wherein the thickness of the unit is likewise continuously orders of magnitude smaller than its length and width.

The display unit according to the present invention is energy-autonomous and therefore does not have to be connected to the on-board power supply of a vehicle. Energy autonomy is achieved via a solar cell, which is transparent and extends across the entire display surface of the display element. This provides the advantage that the size of the display unit is essentially determined by the size of the display surface, and in particular no additional surfaces are required for obtaining electrical energy, for example, due to solar cells arranged next to the display surface. The radiant energy required for energy generation is regularly available in the form of incident sunlight or artificial cabin illumination. Because the display surface of a display unit for a vehicle is generally oriented toward the cabin interior space and is visible, it is ensured that this radiant energy strikes the solar cell and can also actually be converted into electrical energy for operating the display unit. The transparent solar cell may also be a transparent organic solar cell.

In order for the display unit to be able to continue to be operated even in the case of temporarily absent illumination, for example, during the night or in the case of switched-off cabin illumination, or in the case of brief shadowing by a passenger, and thus in the case of a lack of radiant energy, which is suitable for converting into electrical energy, the display unit comprises an energy store which is charged by the solar cell and, during corresponding dark phases, can provide energy for continuing to operate the display unit. In order to control the display unit and in particular the information depicted on the display surface, a control unit is provided.

Even if the solar cell extends across entire display surface, the electrical power to be obtained via the solar cell is limited. This is all the more true because the solar cell is transparent in order to continue to make the information depicted on the display surface visible, which is why, however, a portion of the incident radiant energy, in particular in the visible range, must pass through the solar cell and cannot be converted into electrical energy. In order nonetheless to ensure reliable operation of the display unit, the energy consumption in particular of the display element must be adapted to the available low amount of electrical energy. It is therefore preferred if it is an e-paper display or an OLED display.

An e-paper display is a passive, non-luminous display, which generally consumes energy only if the information to be displayed, i.e., the image content to be displayed, changes. In the case of no change, the image to be displayed is kept stable and unchanged over a longer period of time (generally several weeks), without electrical energy being required therefor. The control unit can be configured to update the image to be displayed on the display surface after a predetermined period of time, even if its content has not changed, in order to constantly ensure a desired depiction on the display surface. An e-paper display is particularly suitable for reproducing information that changes infrequently. It may be configured for displaying information monochromatically or in color.

Alternatively, the use of an OLED display as a display element is also possible. An OLED display is a self-illuminating display that uses little current during operation. Nonetheless, unlike e-paper displays, energy is continuously required for displaying information on the display surface. Given the low amount of energy which is available, display units according to the present invention having OLED displays are suitable particularly for displaying information of which it is known that the information only has to be displayed temporarily. Due to their self-illuminating characteristic, corresponding display elements having an OLED display can also be used in particular for emergency systems, for example, as emergency lighting or escape route marking, in which in case of emergency, the energy supply takes place by means of the energy store, which is arranged directly on the display unit and which can be sufficiently charged by the solar cell during normal operation if the display is deactivated.

The solar cell and/or the energy store are preferably designed in such a way that sufficient energy can be obtained and/or stored over the course of a typical daily cycle so that the operation of the display unit is possible for the entire day, wherein a change in the display content is preferably possible at least once per hour. The latter is in particular significant for ascertaining the amount of energy required for e-paper displays. The amount of energy which can be generated by the solar cell results from the light conditions typically occurring in the interior of the cabin during the course of a day, and is to be greater than or equal to the energy required during the course of the day for operating the display unit.

It is preferred if the energy store and/or the control unit are respectively configured as a layer or are configured together as a common layer of a multilayer structure of the display unit. Because these two elements of the display unit are also designed as layers of a multilayer structure, it is possible to achieve a display unit having lower thickness and without a larger border which is arranged on the sides of the display surface. In order to design the energy store and the control unit as a layer, they may include at least partially printed electronics elements.

Preferably, the outer layer of the display unit on the side facing away from the display surface is a mounting layer, which furthermore preferably has a self-adhesive or magnetically acting surface. In other words, the back side of display unit is to be configured for adhesively or magnetically attaching the unit. Via a corresponding mounting layer, it is possible to attach the display element in a detachable or non-detachable manner, depending on the attachment method.

It is furthermore preferred that the outermost layer of the display unit on the side of the display surface is a transparent protective layer for protecting the layers below from damage. For example, for the case that the solar cell, which is configured as a layer, is easily scratched, damage to the solar cell layer below can be effectively prevented by means of a suitable protective layer.

The display unit may include a touch-sensitive layer for ascertaining contact with the display surface, so that the display unit is not configured exclusively for displaying information, but also for receiving user commands. A touch-sensitive display unit may, for example, be used for controlling the cabin illumination or an air conditioning system. Depending on the technology used for detecting contact, the touch-sensitive layer is to be configured to be transparent, so that, if it is arranged above the display surface, the information displayed on the display surface is in principle visible. If the touch-sensitive layer requires the mechanical application of force for detecting contact, the layers arranged between the touch-sensitive layer and the outside of the display unit on the side of the display surface are to be configured in such a way that the detection of contact is possible by means of the touch-sensitive layer. For example, for this purpose, the individual layers may be configured to be sufficiently elastically deformable.

It is preferred if the display unit is flexible as a whole, i.e., it can be elastically deformed within certain limits. Such flexibility is advantageous in order to be able to use one type of display units at different locations, for example, on both flat and curved inner walls of an aircraft cabin. In order to be able to ensure the flexibility of the display unit as a whole, all layers of the display unit must be elastically deformable.

If the unit has a multilayer structure, the layers of the display unit are connected to one another on the circumferential edge or are provided there with an additional element, in such a way that, even in the case of vibration or other mechanical stress, no foreign matter can get between the individual layers. In particular, the infiltration of moisture into an area between the individual layers is to be prevented. Preferably, the display unit is configured in such a way that it can withstand acceleration loads of more than 5 g without damage. In addition to ensuring the structural integrity of the display unit, this requirement also preferably relates to the mounting layer via which the display unit can be attached inside the aircraft cabin. In this case, the mounting layer is to ensure the secure attachment of the display unit even in the case of acceleration loads of more than 5 g.

In particular in the case of a multilayer structure of the display unit, it is preferred if the display unit is configured in such a way that it withstands regular air pressure changes from normal pressure at sea level up to an equivalent pressure at an elevation of least 2000 m without damage. Corresponding changes in air pressure occur in cabins of passenger aircraft in practice at each start and each landing; thus, the display unit is to withstand this change in air pressure preferably without damage. For this reason, in the case of a multilayer structure, it is, for example, to be ensured that no liquid or gaseous components are embedded between the individual layers, and that the individual layers themselves are sufficiently pressure-proof.

The control unit may include a preferably printed antenna for receiving control signals. Furthermore, the control unit and/or the antenna may be configured for transmitting and receiving control and information signals, preferably according to the IEEE-802.11 and/or Bluetooth Low Energy standard. Via the antenna, the control unit can wirelessly receive the information to be displayed on the display surface and other control signals. The transmission of information to be displayed and other control signals preferably takes place in a secure manner, for example, with the aid of certificates or other known authentication mechanisms. If the display unit is designed to be touch-sensitive, the corresponding contact information may also be transmitted via the antenna in the form of signals. By using a low-energy radio standard, low consumption may be achieved by the control unit. Alternatively or in addition to a wireless interface, the control unit may also include a wired interface, for example, a USB interface, or a device for reading and/or writing data media, for example, SD cards. Data can be transmitted to the control unit or read out from it via corresponding interfaces or writing and/or reading devices.

The energy store may, for example, comprise a printed battery and/or a printed supercapacitor.

The display unit is preferably designed to be flame-retardant. In other words, the display unit is thus to be self-extinguishing within 15 seconds if it is subjected to a Bunsen burner flame for at least 12 seconds. The present invention will now be described by way of example based on an advantageous embodiment, with reference to the appended drawings.

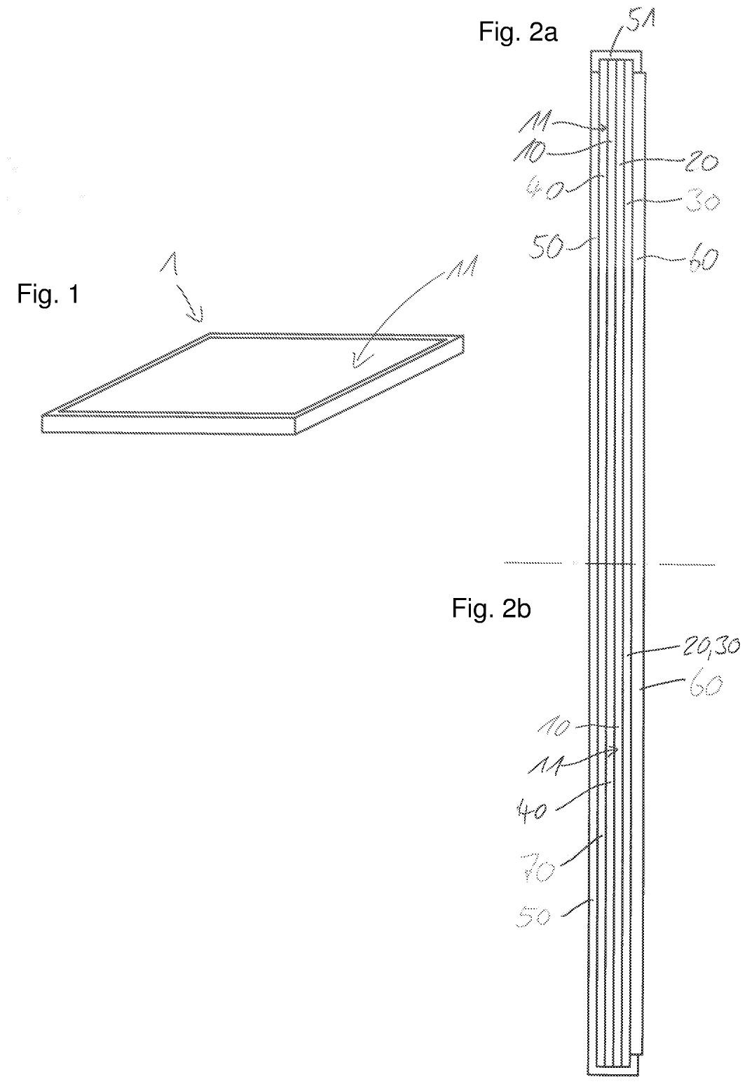

FIG. 1 depicts a first exemplary embodiment of an energy-autonomous display unit 1 according to the present invention. The display unit 1 includes an externally visible display surface 11 of a display element 10, on which any arbitrary information, and in particular changing information, can be displayed. The display element 10 is an e-paper display, which can render information monochromatically or in color, depending on the design.

FIGS. 2a and 2b depict the structure of the display unit 1 in greater detail, in two different embodiment variants.

In the embodiment variant according to FIG. 2a, the display element 10 is configured as a layer of a multilayer structure. A transparent solar cell 40 and a transparent protective layer 50 are arranged on the side of the display surface 11 of the display element 10 as additional layers. Both the solar cell 40 and the protective layer extend across the entire display surface 11 of the display element 10. However, due to the transparent design of the layers 40, 50 in question, the information depicted on the display surface 11 continues to remain externally visible.

On the side of the display element 10 facing away from the display surface 11, two additional layers are provided, of which the first is an energy store 20 in the form of a printed battery, and the other is a control device 30. The control device 30 is designed as a printed electronic system including a microcontroller, a transceiver unit, and an antenna for transmitting and receiving radio signals according to the Bluetooth Low Energy standard.

The outer layer on the side of the display element 10 facing away from the display surface 11 is a mounting layer 60, which has a self-adhesive outer side. Via the mounting layer 60, the display element 1 can be attached to any surfaces. In order also to be able to attach to curved surfaces if needed, the display element 1 is designed to be flexible, whereby all layers of the multilayer structure are in principle elastically deformable.

A protective element 51 is provided circumferentially on the outer edge of the display element 1, which engages around all layers of the display element 1 in such a way that no dirt and no moisture can get between the individual layers from the edge.

FIG. 2b depicts an alternative embodiment variant of the display element 1, wherein essentially only the differences of this embodiment variant will be discussed below.

In this embodiment variant, the energy store 20 and the control device 30 are configured as a single, joint layer in the form of a printed electronic system. In this case, a portion of the layer is provided for the energy store 20; the other portion is provided for the control device 30, in addition to the antenna.

A touch-sensitive layer 70 is provided as a further layer between the solar cell 40 and the protective layer 50. In order for the information displayed on the display surface 11 to continue to remain visible, the touch-sensitive layer 70 is also designed to be transparent. The touch-sensitive layer 70 works resistively. In order to be able to register contact on the display unit 1, the protective layer 50 is sufficiently flexible such that contact made with the display element 1 is transmitted to the touch-sensitive layer 70.

The protective element 51 is designed as one piece with the protective layer 50. The intrinsically transparent protective layer 50 is colored in the areas away from the display surface 11, i.e., in particular on the border, so that it is non-transparent in these areas, which are not significant for the visibility of the information displayed on the display surface 11.

Apart from the touch-sensitivity of the embodiment variant according to FIG. 2b, the function of the display units 1 in both embodiment variants is identical. Via the solar cell 40, incident sunlight or artificial light of cabin illumination is converted into electrical energy which is stored in the energy store 20. The energy store 20 supplies both the control unit 30 and the display element 10 with electrical energy. Because, due to its embodiment as an e-paper display, the display element 10 in practice uses energy only if the displayed information changes, and the control device also uses little energy, for example, due to the use of the Bluetooth Low Energy radio standard, the energy generation by means of the transparent solar cell 40 is sufficient to charge the energy store 20 in such a way that the display element 10 can be reliably operated even in dark phases, for example, during the night.

In the case of the embodiment variant according to FIG. 2b, the control unit 30 is furthermore configured to detect contact on the display surface 11 via the touch-sensitive layer 70. Corresponding contact may be directly transmitted to an external receiver via Bluetooth Low Energy radio transmission, or via the control device 30, first converted into control signals which are then correspondingly transmitted.

While embodiments of the invention have been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. An energy-autonomous display unit for a cabin of a vehicle, the display unit comprising:
a display element for displaying information on a display surface;
an energy store;
a controller; and
a photovoltaic element,
wherein the photovoltaic element is connected to the energy store and is configured to charge the energy store,
wherein the energy store is connected to the display element and the controller for supplying energy,
wherein the controller is configured to control the display element and the information displayed on the display surface,
wherein the photovoltaic element is a transparent solar cell extending across the entire display surface of the display element, and
wherein the photovoltaic element is a first layer on the display element.

2. The display unit as claimed in claim 1, wherein the display element is an e-paper display or an OLED display, and wherein the display element is a further layer of a multilayer structure of the display unit.

3. The display unit as claimed in claim 1, wherein the energy store or the controller are respectively configured as a layer or are configured together as a common layer of a multilayer structure of the display unit.

4. The display unit as claimed in claim 1, wherein an outermost layer of the display unit on a side facing away from the display surface is a mounting layer.

5. The display unit as claimed in claim 1, wherein an outermost layer of the display unit on a side of the display surface is a transparent protective layer that is configured to protect layers below from damage.

6. The display unit as claimed in claim 1, wherein the display unit comprises a touch-sensitive layer for ascertaining contact with the display surface, wherein the touch-sensitive layer or layers arranged on a side of the display surface between the touch-sensitive layer and the outside of the display unit enable the detection of contact by means of the touch-sensitive layer.

7. The display unit as claimed in claim 1, wherein the display unit is flexible and all layers of the display unit are elastically deformable.

8. The display unit as claimed in claim 1, wherein layers of the display unit are connected to one another on a circumferential edge or are provided on the circumferential edge with an additional element in such a way that no foreign matter can get between the layers.

9. The display unit as claimed in claim 1, wherein the controller comprises a printed antenna for receiving control signals.

10. The display unit as claimed in claim 3, wherein the controller or antenna are configured to transmit and receive control and information signals.

11. The display unit as claimed in claim 4, wherein the energy store comprises a printed battery or a printed super-capacitor.

12. The display unit as claimed in claim 1, wherein the solar cell or the energy store are designed in such a way that sufficient energy is obtained or stored over a course a typical daily cycle such that the operation of the display unit is possible for the entire day, wherein a change in the display content is preferably possible at least once per hour.

13. The display unit as claimed in claim 3, wherein the energy store or the controller comprise at least partially printed electronics elements.

14. The display unit as claimed in claim 4, wherein the mounting layer has a self-adhesive or magnetically acting surface.
